(19) United States
(12) Patent Application Publication
(10) Pub. No.: US 2025/0113735 A1
(43) Pub. Date: Apr. 3, 2025

(54) INFRARED IMAGING MICROBOLOMETER

(71) Applicant: LYNRED, Palaiseau (FR)

(72) Inventors: Marc Guillaumont, Grenoble (FR); Willy Ludurczak, Lyon (FR)

(21) Appl. No.: 18/832,275

(22) PCT Filed: Feb. 21, 2023
(86) PCT No.: PCT/FR2023/050243

§ 371 Date: Jul. 23, 2024

(30) Foreign Application Priority Data
Mar. 11, 2022 (FR) 2202135

(51) Int. Cl. H10N 15/10; G01J 5/00; G01J 5/20

(52) U.S. Cl. CPC H10N 15/15; G01J 5/20; G01J 2005/0077

(57) ABSTRACT

This infrared imaging microbolometer integrates a membrane mounted in suspension above a substrate by means of holding arms attached to anchor nails. The microbolometer includes a support layer extending within the membrane holding arms and electrodes arranged on the support layer and in contact with the anchor nails. Each electrode extends within a holding arm. A thermoresistive material is arranged within the membrane in electric contact with the electrodes. The microbolometer also includes at least an upper encapsulation layer for the holding arms and the thermoresistive material and a lateral encapsulation layer for the holding arms arranged in contact with the lateral edges of said holding arms, the lateral encapsulation layer being resistant to etching based on hydrofluoric acid.

### TECHNOLOGICAL FIELD

The present invention relates to the field of electromagnetic radiation detection and, more specifically, to the detection of infrared radiation. The invention concerns an infrared imaging microbolometer having a high sensitivity.

### BACKGROUND

In the field of detectors implemented for infrared imaging, it is known to use devices arranged in array form, likely to operate at room temperature, that is, requiring no cooling to very low temperatures, conversely to detection devices called “quantum detectors” which require an operation at very low temperature.

These detectors conventionally use the variation of a physical quantity of a material or assembly of suitable materials according to temperature, in the vicinity of 300 K.

In the specific case of microbolometric detectors, the most commonly used, this physical quantity is the electric resistivity, but other quantities may be used, such as the dielectric constant, the biasing, the thermal expansion, the refraction index, etc.

Such a non-cooled detector generally associates:
means for absorbing the thermal radiation and for converting it into heat;
means for thermally insulating the detector, in such a way as to enable it to heat under the action of the thermal radiation;
thermometry means which, in the context of a microbolometric detector, implement a resistive element having its resistance varying along with temperature;
and means for reading the electric signals supplied by the thermometry means.

Detectors intended for thermal, or infrared, imaging are conventionally manufactured in the form of an array of elementary detectors, forming image points or pixels, according to one or two dimensions. To guarantee the thermal insulation of detectors, the latter are suspended above a substrate via holding arms.

The substrate usually comprises means for sequentially addressing the elementary detectors and means for electrically exciting and pre-processing the electric signals generated from these elementary detectors. This substrate and the integrated means are commonly designated with the term “readout circuit”.

To obtain a scene via these detectors, this scene is captured through adapted optics on the array of elementary detectors, and rated electric stimuli are applied via the readout circuit to each of the elementary detectors, or to each row of such detectors, to obtain an electric signal forming the image of the temperature reached by each of said elementary detectors. This signal is more or less elaborately processed by the readout circuit, and then possibly by an electronic device external to the package to generate the thermal image of the observed scene.

More specifically, an elementary detector is formed of a membrane held in fixed suspension above the substrate by the holding arms. The membrane integrates a thermoresistive material which performs a transduction of the infrared radiation, forming the thermometry means.

The measurement of the electric resistance of the thermoresistive material is performed by two electrodes, for example metallic, extending under the thermometric material and in the holding arms.

In addition to the reading of the signal across the thermoresistive material, the electrodes may also have the function of absorbing at least a portion of the infrared flux to transform it into heat and transmit it to the thermoresistive material.

In this case, the absorbed quantity of infrared radiation is dependent on the surface area of this absorber. To optimize the absorption of the infrared radiation, the electrodes cover a maximum surface area in the pixel footprint. In practice, the surface area of the electrodes is limited by that of the membrane.

The thickness and the electric resistivity of the electrodes is adjusted so that its effective impedance per square is adapted to that of vacuum: Z₀=377 ohm/square.

Elementary detectors are conventionally formed on a silicon substrate which comprises the readout circuit. By means of metal or dielectric layer deposition methods, photolithography methods, and etch methods of microelectronics, a sacrificial layer is formed on the substrate, after which a membrane sensitive to infrared radiation is formed on this sacrificial layer while structuring this membrane to ensure an electric continuity between the latter and the readout circuit.

According to different approaches, the sacrificial layer is made of polyimide or of a silicon oxide since these materials may be etched by means of an isotropic method enabling to remove said sacrificial layer under the membrane and to leave this membrane in a state suspended above the substrate. This property is necessary for the operation of the elementary detectors. Conventionally-implemented etch methods are oxygen-based plasma methods or etch methods based on hydrofluoric acid, respectively dedicated to the removal of a sacrificial layer made of polyimide or of silicon oxide.

It is particularly advantageous to use a silicon oxide sacrificial layer associated with an etching based on hydrofluoric acid. Indeed, this enables to re-use the highest-performance methods of microelectronics. Thus, it is possible to obtain a better etching fineness and, thereby, to obtain smaller pixels pitches at the required performance as compared with the use of a sacrificial layer made of polyimide associated with an oxygen-based etching.

The membrane is formed by means of at least one thermoresistive material generally obtained by a deposition made of an alloy of silicon and of germanium, or by a deposition made of vanadium oxide. This layer may also include elements such as nitrogen, boron, carbon. To structure the membrane, other materials are necessary, and this membrane thus is the result of a stack comprising the thermoresistive material, to which are added one or a plurality of dielectric materials and electrodes formed by metal deposition. This stack is structured into a plurality of sequences of deposition, photolithography, and etching to form the elementary detector, also called microbolometer.

FIGS. 1a to 1f illustrate a method of forming a microbolometer 100 of state of the art, such as for example described in document EP 3 182 081.

A first step, illustrated in FIG. 1a, comprises depositing and structuring a sacrificial layer 12 and a support layer 13 on a substrate 11 integrating the readout circuit. The structuring of these two layers 12, 13 enables to obtain openings where anchor nails 14 can be formed.

As illustrated in FIG. 1b, the forming of anchor nails 14 in the openings aims at obtaining a conductive pad extending at least all the way to the upper surface of support layer 13.

At least two electrodes 16 are then deposited and structured on support layer 13 and on the upper portion of anchor nail 14. When the support layer 13 having electrodes 16 deposited thereon has a low electric resistivity, it is necessary to remove by a distance d1 the ends 37 of electrodes 16, to limit leakage currents between said electrodes 16. This distance d1 may amount to approximately 50% of the pixel pitch, that is, 50% of the distance between anchor nails 14.

A thermoresistive material 18 is then deposited on support layer 13 and on electrodes 16 to ensure an electric continuity between said electrodes 16. An etching of this thermoresistive material 18 enables to delimit its location at the center of microbolometer 100, that is, in the area intended to form the membrane 20 thereof, as illustrated in FIG. 1d.

The etching of thermoresistive material 18 is conventionally carried out by reactive ion etching, also called RIE, by stopping the etching on the two electrodes 16. This etch step raises a technical issue since both electrodes 16 are often particularly thin, with a thickness typically smaller than 20 nanometers. Now, the RIE implemented to delimit the location of thermoresistive material 18 risks, if it is not perfectly calibrated, deteriorating electrodes 16 and decreasing the performance of microbolometer 100.

As illustrated in FIG. 1e, an upper encapsulation layer 190 is then deposited on electrodes 16 and on thermoresistive material 18. This upper encapsulation layer 190 enables to form an upper and lateral protection to thermoresistive material 18, as well as an upper protection to electrodes 16. Indeed, to obtain a low-frequency noise coefficient, it is known to use a thermoresistive material 18 made of vanadium oxide. However, vanadium oxide is sensitive to the hydrofluoric acid conventionally used during the step of removal of a sacrificial layer 12 made of silicon dioxide.

Thus, it is often necessary to protect thermoresistive material 18, at least so that the step of removal of the sacrificial layer does not deteriorate said material. For this purpose, upper encapsulation layer 190 is conventionally deposited to encapsule thermoresistive material 18.

This upper encapsulation layer 190 also has the function of encapsulating electrodes 16 to ensure the mechanical resistance of membrane 20 according to the desired application, that is, according to the desired resistance to shocks of microbolometer 100.

Further, it is desired to limit the thermal conduction of holding arms 21 to insulate membrane 20 from the temperature of substrate 11.

Thus, for each microbolometer 100, there exists an ideal thickness of holding arms 21 and of upper encapsulation layer 190 for which holding arms 21 have a minimum thickness and thus a minimum heat conductance, while respecting the desired mechanical constraints.

To obtain a microbolometer 100 having a high sensitivity, it is desired to have a low heat conductance of holding arms 21 and a significant infrared radiation collection surface area. For this purpose, electrodes 16 preferably carry out the function of an infrared radiation absorber. Apart from electrodes 16, another absorbing material may also be deposited on upper encapsulation layer 190, above the membrane, as for example described in document EP 3 870 945. Thus, the association of electrodes 16 and of the absorbing material enables to obtain a significant infrared radiation collection surface area.

However, the deposition of such an absorbing material requires depositing upper encapsulation layer 190 in two steps, before and after the deposition of said absorbing material, to avoid for the latter to be directly deposited on thermometric material 18 and to protect it from the etching of sacrificial layer 12.

After the complete deposition of this upper encapsulation layer 190, in one or two steps, layers 13, 16, and 190 are then etched according to the pattern desired to form the holding arms 21 of membrane 20.

Finally, step 1f illustrates the removal of sacrificial layer 12, thus clearing membrane 20 in suspension on anchor nails 14 via holding arms 21.

During this clearing step, thermometric material 18 and the possible absorbing material are protected from the etching of sacrificial layer 12 by support layer 13 and upper encapsulation layer 190. These layers 13 and 190 are thus selected to resist to the etch method implemented to obtain the removal of sacrificial layer 12, for example the etching based on oxygen or based on hydrofluoric acid, while thermometric material 18 and the possible absorbing material may be respectively selected for their thermal-electrical transduction and infrared radiation collection performance.

Similarly, the patterns of the holding arms 21 of membrane 20 being formed before the clearing step, the etching also etches the side walls of holding arms 21, so that electrodes 16 and all the materials possibly integrated in holding arms 21, between layers 13 and 190, must also resist to the etching of sacrificial layer 12.

This constraint greatly limits the possibilities of forming of holding arms 21 and, in certain cases, it is not possible to use the highest-performance materials in terms of electric resistivity, of thermal resistance, and/or of mechanical resistance to form said holding arms 21 due to this constraint of resistance to the etching of sacrificial layer 12, particularly when the latter is made of silicon oxide and the etching implements the hydrofluoric acid.

The technical issue that the invention aims at solving is to obtain an infrared imaging microbolometer in which the materials integrated in the holding arms are protected from the etching of the sacrificial layer based on hydrofluoric acid to be able to use higher-performance materials in terms of electric resistivity, of thermal resistance, and/or of mechanical resistance to form the holding arms, thus improving the microbolometer performance.

### SUMMARY OF THE DISCLOSURE

To address this technical issue, the invention provides forming the holding arms with a lateral encapsulation layer of the holding arms resistant to the etching of the sacrificial layer, that is, resistant to the etching based on hydrofluoric acid, to protect the materials integrated in the holding arms.

Thus, the invention concerns an infrared imaging microbolometer integrating a membrane mounted in suspension above a substrate by means of holding arms attached to anchor nails, the microbolometer comprising:
a support layer extending within the membrane and holding arms;
electrodes arranged on the support layer and in contact with the anchor nails, each electrode extending within the holding arms;
a thermoresistive material arranged within the membrane in electric contact with the electrodes; and
at least an upper encapsulation layer for the holding arms and the thermoresistive material.

The invention is characterized in that the microbolometer also comprises a lateral encapsulation layer for the holding arms arranged in contact with the lateral edges of said holding arms, said lateral encapsulation layer being resistant to etching based on hydrofluoric acid, to form, with the support layer and the upper encapsulation layer of the holding arms, an encapsulation hermetic to etching based on hydrofluoric acid.

In the meaning of the invention, a “hermetic encapsulation” indicates that the holding arms are protected from the etching based on hydrofluoric acid by means of the association of the lateral encapsulation layer, of the support layer, and of the upper encapsulation layer of the holding arms.

By performing the encapsulation of the holding arms, the invention enables to use high-performance materials in terms of electric resistivity, of thermal resistance, and/or of mechanical resistance inside of the holding arms. For example, the material forming the electrodes may be sensitive to the removal of the sacrificial layer without risking being deteriorated by the step of removal of said sacrificial layer. For example, it is now possible to use the titanium in its metallic form to form the electrodes, although this material is not compatible with an etching based on hydrofluoric acid.

Similarly, it is possible to integrated in the holding arms, on either side of the electrodes, two layers of materials having an electric resistivity sufficiently high to allow the bringing together of the electrodes at the center of the membrane by limiting leakage currents.

For this purpose, these two resistive layers are in continuity with each other between the ends of the electrodes present within the membrane so as to form an insulating barrier between said ends. Thus, this embodiment enables to obtain a significant collection surface area without using an absorbing material deposited on the thermometric material.

In this embodiment, the microbolometer also comprises:
a lower resistive layer arranged between the support layer and the electrodes; and
an upper resistive layer arranged between the electrodes and the upper encapsulation layer of the holding arms;
the lower and upper resistive layers being in continuity with each other between ends of the electrodes extending within the membrane, thus forming an insulating barrier between the electrodes, thus enabling to increase the surface area of the electrodes extending within the membrane.

In the meaning of the invention, a “resistive” layer corresponds to a layer having an electric resistivity at least 10,000 times greater than that of the thermoresistive material. For example, the thermoresistive material may be made of an amorphous alloy, having a high content of silicon, of vanadium oxide, of titanium oxide, or of nickel oxide. Thus, the thermoresistive material may have an electric resistivity in the range from 0.1 to 100 Ohm·cm. Conversely, the lower and upper resistive layers may have an electric resistivity greater than 10⁴ Ohm·cm.

The electric resistivity of the resistive layers mainly aims at avoiding leakage currents likely to occur between the ends of the electrodes extending within the membrane. Thus, the electric resistivity may be searched for according to the desired proximity of implantation of the electrodes.

Apart from the electric resistivity properties of the lower and upper resistive layers, these layers may also be sized, in terms of thickness or of constituent material, to meet the thermal resistance and mechanical resistance needs of the holding arms. To meet these different constraints, the lower and upper resistive layers may be made of hafnium dioxide, of silicon nitride, of silicon oxide, of silicon oxynitride, of boron nitride, of aluminum nitride, of silicon carbide, of silicon carbonitride, of silicon boride, of silicon oxyboride, of silicon boronitride, of silicon borocarbide, or of silicon oxycarbide.

In the meaning of the invention, and in the rest of the disclosure, the “height” of the microbolometer corresponds to the dimension perpendicular to the plane of the substrate having the microbolometer attached thereto.

Thus, the support layer forms a “lower” encapsulation layer for the membrane and the holding arms; it corresponds to the layer closest to the substrate and it extends in a lower plane of the membrane and of the holding arms, parallel to the plane of the substrate.

The “upper” encapsulation layer corresponds to the encapsulation layer most distant from the substrate, and it extends in an upper plane of the membrane and of the holding arms, also parallel to the plane of the substrate.

The invention may use a plurality of different upper encapsulation layers: an upper encapsulation layer for the membrane and an upper encapsulation layer for the holding arms.

Further, the “lower” resistive layer corresponds to the layer placed in contact with the electrodes closest to the substrate, and the “upper” resistive layer corresponds to the layer placed in contact with the electrodes most distant from the substrate.

The “lateral” encapsulation layer of the holding arms corresponds to the thickness of material present on the lateral circumference of the holding arms, between the support layer and the upper encapsulation layer of the holding arms. The lateral encapsulation layer thus extends in a plane perpendicular to the planes of the lower encapsulation layer and of the upper encapsulation layer of the holding arms.

Preferably, the upper encapsulation layer of the holding arms and the lateral encapsulation layer are of different natures or thicknesses. For example, the upper encapsulation layer of the holding arms may be made of boron nitride, of alumina, of silicon carbide, or of aluminum nitride. The lateral encapsulation layer may be made of an alloy with a high content of silicon or boron, of aluminum oxide, of aluminum nitride, of silicon carbide, or of boron carbide. For example, the lateral encapsulation layer may comprise at least 25% of silicon, possibly alloyed with nitrogen, boron, carbon, or hydrogen.

Alternatively, the upper encapsulation layer of the holding arms and the lateral encapsulation layer of the holding arms are made of a same material, typically an amorphous alloy having a high content of silicon or boron, of aluminum oxide, of aluminum nitride, of silicon carbide, or of boron carbide.

Boron nitride, alumina, aluminum nitride, silicon carbide as well as a silicon-rich amorphous alloy have the property of resisting to an etching based on hydrofluoric acid (HF) conventionally used to remove a sacrificial layer made of silicon oxide (SiOx).

When the different encapsulation layers are made of the same material, it is possible to distinguish these different layers by their respective thickness.

By thickness, there is meant:

regarding the upper encapsulation layer of the holding arms, the dimension perpendicular to the plane of the substrate in which the microbolometer is inscribed; and

regarding the lateral encapsulation layer of the holding arms, a dimension parallel to said plane of the substrate; this last thickness is typically measured at the base of the lateral encapsulation layer.

Further, the lateral encapsulation layer of the holding arms may comprise a lug protruding from the upper encapsulation layer of the holding arms by at least 10 nanometers. This characteristic shape may result from the forming of the lateral encapsulation layer independently from the upper encapsulation layer of the holding arms.

### BRIEF DESCRIPTION OF THE DRAWINGS

The invention will be well understood on reading of the following description, the details of which are given as an example only, and developed in relation with the appended drawings, in which identical references relate to identical elements:

FIGS. 1a-1f illustrate the steps of forming of a microbolometer of the state of the art;

FIG. 2a is a simplified cross-section view of a microbolometer according to a first embodiment of the invention;

FIG. 2b is a partial enlargement of the simplified cross-section view of FIG. 2a;

FIG. 3 is a simplified cross-section view of a microbolometer according to a second embodiment of the invention;

FIG. 4 is a simplified cross-section view of a microbolometer according to a third embodiment of the invention;

FIG. 5 is a simplified cross-section view of a microbolometer according to a fourth embodiment of the invention;

FIG. 6 is a simplified cross-section view of a microbolometer according to a fifth embodiment of the invention;

FIG. 7 is a simplified cross-section view of a microbolometer according to a sixth embodiment of the invention; and

FIG. 8 is a simplified cross-section view of a microbolometer according to a seventh embodiment of the invention.

### DETAILED DESCRIPTION

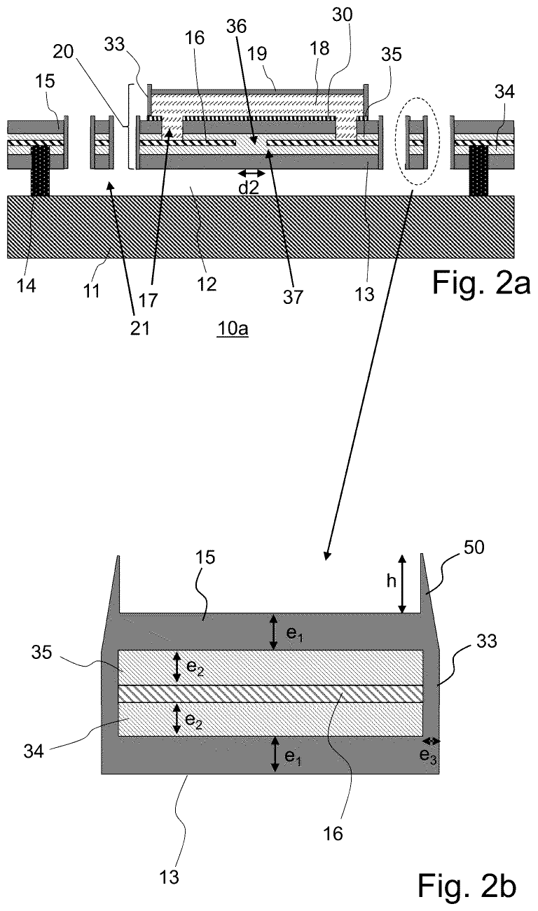

As illustrated in FIG. 2a, the invention aims at a microbolometer 10a comprising a membrane 20 mounted in suspension on a substrate 11. Substrate 11 conventionally integrates a readout circuit, that is, an assembly of components particularly allowing the biasing, the addressing, and the measurement of the resistance of the membrane 20 of microbolometer 10a. More specifically, the readout circuit performs the measurement of the resistance of a thermoresistive material 18 encapsulated in membrane 20.

For this purpose, thermoresistive material 18 is electrically connected to the readout circuit by electrodes 16 and anchor nails 14. Membrane 20 has the function of performing a thermal/resistive transduction of the infrared radiation.

To limit the influence of the temperature of substrate 11, this membrane 20 is mounted in suspension on anchor nails 14 via holding arms 21. Thus, anchor nails 14 extend perpendicularly with respect to substrate 11, and the holding arms and membrane 20 extend in a plane parallel to the plane of substrate 11. There exist two major forms of microbolometers: microbolometers suspended between two anchor nails 14 and microbolometers suspended between four anchor nails 14.

Whatever the microbolometer used, these anchor nails 14 may be made of a metallic material, such as titanium nitride, copper, tungsten, or aluminum. They may have a cylindrical transverse cross-section with a diameter close to 500 nanometers.

To guarantee the mechanical structure of membrane 20 and of holding arms 21, a support layer 13 forms the lower layer of membrane 20 and of holding arms 21. This support layer 13 may, for example, be made of an amorphous alloy having a high content of silicon, of silicon carbide, of alumina, or of aluminum nitride, and have a thickness in the range from 10 to 100 nanometers.

According to the invention, a lower resistive layer 34 is arranged between support layer 13 and electrodes 16. This lower resistive layer 34 may be made of hafnium dioxide, of silicon nitride, of silicon oxide, of silicon oxynitride, of boron nitride, of aluminum nitride, of silicon carbide, of silicon carbonitride, of silicon boride, of silicon oxyboride, of silicon boronitride, of silicon borocarbide, or of silicon oxycarbide.

Support layer 13 and lower resistive layer 34 are run through by anchor nails 14. Thus, electrodes 16 are bonded to lower resistive layer 34 and to the upper end of anchor nails 14, to ensure an electric contact with these anchor nails 14. These electrodes 16 may be made of titanium nitride with a thickness in the range from 5 to 20 nanometers. Further, these electrodes 16 are structured in the central portion of membrane 20 so that the measurement of the electric resistance between two electrodes 16 enables to measure the electric resistance of thermoresistive material 18. Conversely to the state of the art, the ends 37 of electrodes 16 may be very close to one another.

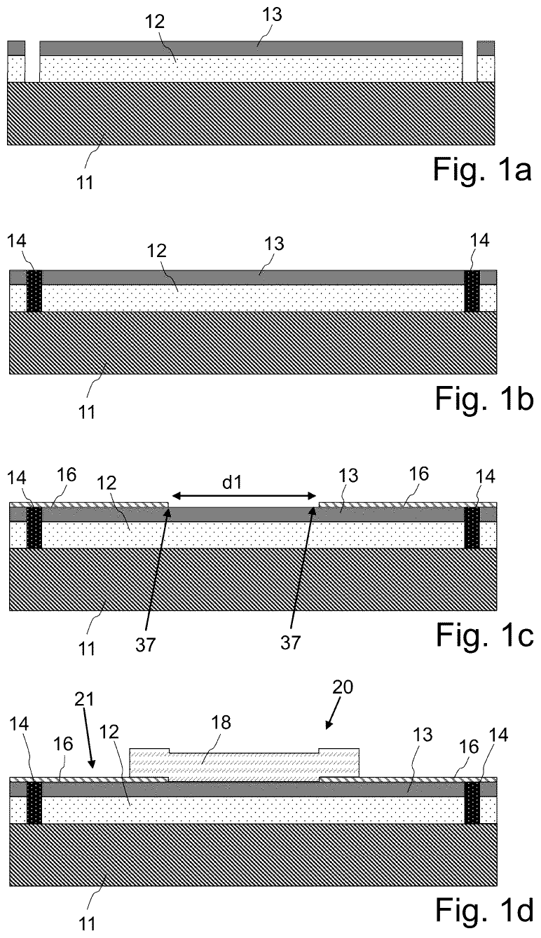

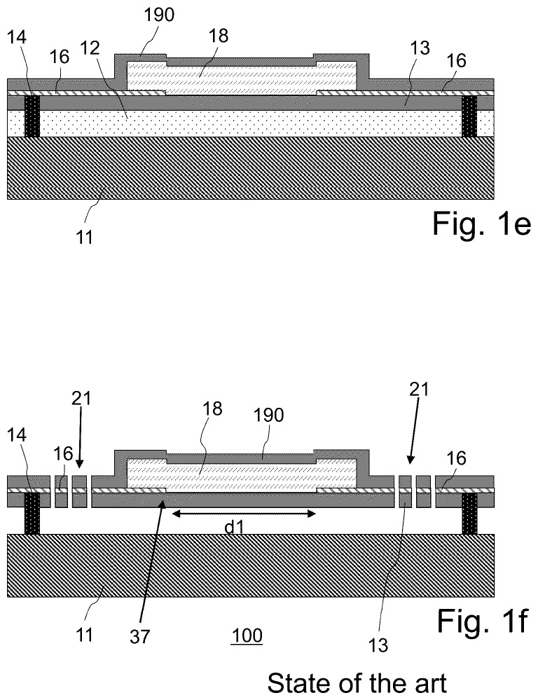

For example, said ends 37 may be distant by a distance d2, shorter than 500 nanometers, typically between 200 nanometers and 1 micrometer. It should be noted that a variation in the topology of the layers deposited on electrodes 16 may appear due to this distance d2, similarly to the topology variation illustrated in FIG. 1f. However, given the short distance d2 as compared with the distance d1 of FIG. 1f and the low thickness of electrodes 16, this topology may be negligible so that this topology variation is not shown in FIGS. 2 to 8.

Further, the material forming electrodes 16 may be selected only to meet the constraints of electric resistivity, of heat conductivity, or of infrared radiation collection, independent from the constraints of resistance to the removal of sacrificial layer. For example, it is now possible to form titanium electrodes 16 in metal form, or even made of copper, chromium, cobalt, or aluminum.

To increase the surface area of electrodes 16, an upper resistive layer 35 is arranged between electrodes 16 and an upper encapsulation layer 15 of the holding arms. This upper resistive layer 35 is preferably made of the same material as the lower resistive layer 34, and it extends between the ends 37 of electrodes 16 to form an insulating barrier 36 between electrodes 16.

As illustrated in FIG. 2b, upper resistive layer 35 preferably has a thickness e₂ equivalent to the thickness e₂ of lower resistive layer 34.

The upper encapsulation layer 15 of the holding arms may be made of an amorphous silicon-rich alloy, possibly alloyed with nitrogen, boron, carbon, or hydrogen, with a thickness e₁ equal to the thickness of support layer 13, these two layers forming the encapsulation layers of holding arms 21.

For a numerical example, with encapsulation layers 13, 15 of holding arms 21 made of an amorphous alloy having a high content of silicon or of boron, of aluminum oxide, of aluminum nitride, of silicon carbide, or of boron carbide, resistive layers 34-35 made of hafnium dioxide may be used since this material has a low heat conductivity, in the order of 0.35 W/(m·K) and a significant mechanical resistance, that is, a Young's modulus close to 150 GPa.

For example, considering holding arms 21 having a fixed 108-nanometer thickness, with electrodes 16 having an 8-nanometer thickness and encapsulation layers 13, 15 having a total thickness of 100 nanometers, it is possible to estimate the advantage of the integration of resistive layers 34-35 instead of a portion of the volume of encapsulation layers 13, 15.

Typically, with the same total 100-nanometer thickness of encapsulation layers 13, 15, the effective heat conductivity of holding arms 21 may be typically in the order of three times lower for a thickness e₂ of 20 nanometers of each resistive layer 34-35, as compared with a zero thickness e₂. The integration of resistive layers 34-35 thus enables to substantially decrease the heat conductivity of holding arms 21.

In addition to support layer 13, resistive layers 34-35, electrodes 16, and the upper encapsulation layer of holding arms 15, and holding arms 21 may also comprise a stop layer 30 deposited on the upper encapsulation layer 15 of holding arms. This stop layer 30 may, for example, be made of boron nitride or of aluminum nitride, and have a thickness in the range from 5 to 100 nanometers. Further, this stop layer 30 may be completed or replaced with an alumina layer and/or a silicon carbide layer with a thickness in the range from 10 to 100 nanometers.

In the example of FIG. 2a, this stop layer 30 is present on the upper encapsulation layer 15 of holding arms, limitingly at membrane 20. In this embodiment, thermoresistive material 18 is deposited on stop layer 30 and on electrodes 16 through openings 17 formed through the upper resistive layer 35, the upper encapsulation layer 15 of the holding arms, and stop layer 30. Preferably, thermoresistive material 18 is made of vanadium oxide deposited with a thickness in the range from 10 to 200 nanometers.

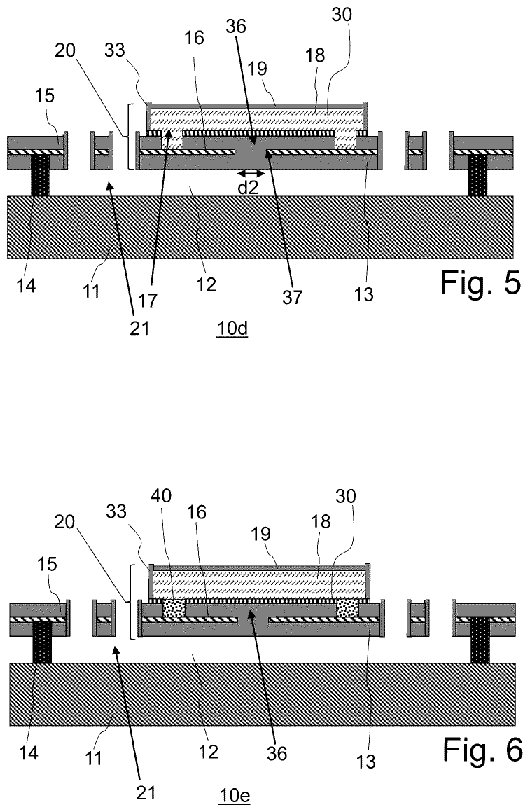

The embodiment of FIG. 5 illustrates a microbolometer 10d formed similarly to that of FIG. 2a but without resistive layers 34 and 35.

The example of the embodiment of FIG. 8 is simpler. Indeed, microbolometer 10g comprises a thermoresistive material 18 deposited on electrodes 16 similarly to the state of the art. Further, the electrodes 16 of FIG. 8 are also encapsulated between a support layer 13 and an upper encapsulation layer 15 of the holding arms and of thermoresistive material 18. In addition to these elements shown in FIG. 1f of the state of the art, microbolometer 10g also comprises a lateral encapsulation layer 33 of holding arms 21 arranged in contact with the lateral edges of said holding arms 21.

This embodiment enables to use any material for electrode 16, in particular materials having a very low heat conductivity but not compatible with the release based on hydrofluoric acid. According to the gain on this parameter, as well as the respective volumes of the materials, the gain may be significant despite the addition of lateral encapsulation 33.

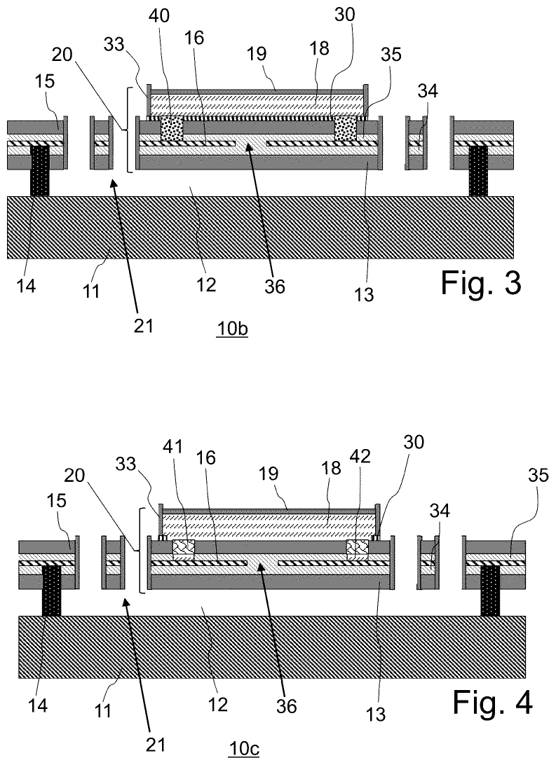

In the embodiment of FIG. 3, microbolometer 10b comprises a thermoresistive material 18 deposited on stop layer 30 and on conductive vias 40 formed in openings 17. Preferably, conductive vias 40 are made of tungsten or of tungsten silicide. The thickness of conductive vias 40 is in the range from 100 to 300 nanometers. To guarantee the filling of openings 17, the thickness of deposition of conductive vias 40 is preferably greater than half the width of openings 17. The filling of openings 17 may also be obtained by the deposition of a thin film of titanium nitride, deposited by chemical vapor deposition, followed by the CVD or PVD deposition of the tungsten or of the tungsten silicide. Thus, a layer of titanium nitride having a thickness in the range from 10 to 50 nanometers may be used to form the external walls of conductive vias 40.

The embodiment of FIG. 6 illustrates a microbolometer 10e formed similarly to that of FIG. 3 but without resistive layers 34 and 35.

In the embodiment of FIG. 4, microbolometer 10c comprises a thermoresistive material 18 deposited on a stop layer 30 etched at the center of membrane 20 and only limited at the lateral edges thereof. At the center of the membrane, thermoresistive material 18 is deposited on support layer 13 and on siliciding areas 41 formed in the upper encapsulation layer 15 of the holding arms, when the latter incorporates silicon. To form the electric contact between electrodes 16 and siliciding areas 41, a metallic material 42 may be locally implanted in upper resistive layer 35.

These siliciding areas 41 may be obtained by incorporation of a metallic siliciding material into a dielectric layer or by local implantation. For example, the upper encapsulation layer 15 of the holding arms may be made of an amorphous alloy with a high content of silicon or boron, of aluminum oxide, of aluminum nitride, of silicon carbide, or of boron carbide. The metallic siliciding material may be made of nickel or of cobalt and possibly with added platinum, to form nickel silicide.

To obtain a local deposition of the metallic siliciding material, a sacrificial layer may be deposited on the upper encapsulation layer 15 of the holding arms, and openings may be structured in this sacrificial layer to reach said upper encapsulation layer 15 of the holding arms. The metallic siliciding material may then be deposited on the sacrificial layer and in the openings.

For example, the metallic siliciding material may be deposited with a thickness in the range from 5 to 50 nanometers.

The incorporation of the metallic siliciding material in the upper encapsulation layer 15 of the holding arms and in the upper resistive layer 35 may then be performed by a diffusion step obtained by thermal anneal, with a temperature in the range from 100° C. to 200° C. for a duration of at least 30 seconds. This thermal anneal enables to obtain siliciding areas 41 in which at least part of the atoms of the metallic siliciding material are present.

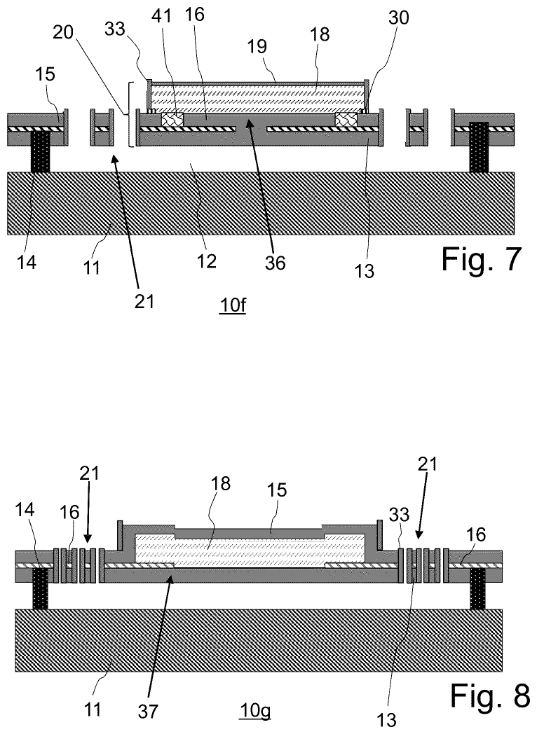

The embodiment of FIG. 7 illustrates a microbolometer 10f formed similarly to that of FIG. 4 but without resistive layers 34 and 35.

Whatever the embodiment, thermoresistive material 18 is deposited in electric contact with electrodes 16.

The upper surface of thermoresistive material 18 is protected by an upper encapsulation layer 19 of the membrane, which may be different from the upper encapsulation layer 15 of the holding arms. This upper encapsulation layer 19 of the membrane may be formed of a stop layer, for example made of boron nitride or of aluminum nitride with a thickness in the range from 10 to 100 nanometers. As a variant, as illustrated in FIGS. 3 to 5, this upper encapsulation layer 19 of the membrane may be made of a layer of silicon-rich amorphous alloy with a thickness in the range from 10 to 100 nanometers.

Thermoresistive material 18 and holding arms 21 are also laterally protected by a lateral encapsulation layer 33.

This lateral encapsulation layer 33 may be made of a layer of silicon-rich amorphous alloy with a thickness e₃ in the range from 5 to 50 nanometers. Lateral encapsulation layer 33 may be very thin to ensure a very good hermeticity to etching based on hydrofluoric acid while guaranteeing the addition of a minimum quantity of material to avoid degrading the thermal insulation of thermoresistive material 18.

Preferably, the upper encapsulation layer 15 of the holding arms, the lateral encapsulation layer 33, and the upper encapsulation layer 19 of the membrane are formed by at least two different depositions, so that the thickness and/or the nature of these layers differ between these layers.

More particularly, as illustrated in FIG. 2b, the thickness e₁ of the upper encapsulation layer 15 of the holding arms is different from the thickness e₃ of lateral encapsulation layer 33.

As illustrated in FIG. 2b, lateral encapsulation layer 33 extending in a plane perpendicular to the planes of support layer 13 and of the upper encapsulation layer 15 of the holding arms, the thickness e₃ of said lateral encapsulation layer 33 corresponds to the thickness of material present around holding arms 21.

The method of forming this lateral encapsulation layer 33 may induce the forming of a lug 50 protruding from the upper encapsulation layer 15 of the holding arms by a height h of at least 10 nanometers.

These microbolometers 10a-10g may be formed by methods using sacrificial layers, particularly the methods disclosed in documents FR 3 098 904 and WO 2018/122382.

Generally, the invention provides forming holding arms 21 comprising a lateral encapsulation layer 33 enabling to limit the constraints of selection of materials integrated in holding arms 21. It is now possible to use higher-performance materials in terms of electric resistivity, of thermal resistance, and/or of mechanical resistance to form the holding arms.

The invention thus enables to obtain a microbolometer 10a-10g having an improved performance.

1. An infrared imaging microbolometer integrating a membrane mounted in suspension above substrate by means of holding arms attached to anchor nails, the microbolometer comprising:
a support layer extending within the membrane and holding arms;
electrodes arranged on the support layer and in contact with the anchor nails, each electrode extending within a holding arm;
a thermoresistive material arranged within the membrane in electric contact with the electrodes; and
at least an upper encapsulation layer for the holding arms and the thermoresistive material;
wherein the microbolometer also comprises a lateral encapsulation layer for the holding arms arranged in contact with lateral edges of said holding arms, said lateral encapsulation layer being resistant to etching based on hydrofluoric acid so as to form, with the support layer and the upper encapsulation layer of the holding arms, an encapsulation hermetic to etching based on hydrofluoric acid.

2. An infrared imaging microbolometer according to claim 1, wherein the upper encapsulation layer of the holding arms and the lateral encapsulation layer of the holding arms are of distinct natures.

3. An infrared imaging microbolometer according to claim 1, wherein the upper encapsulation layer of the holding arms and the lateral encapsulation layer of the holding arms have distinct thicknesses.

4. An infrared imaging microbolometer according to claim 1, wherein the lateral encapsulation layer of the holding arms comprises a lug protruding from the upper encapsulation layer of the holding arms by at least 10 nanometers.

5. An infrared imaging microbolometer according to claim 1, wherein the lateral encapsulation layer of the holding arms and the upper encapsulation layer of the holding arms are made of an amorphous alloy with a high content of silicon or boron, of aluminum oxide, of aluminum nitride, of silicon carbide, or of boron carbide.

6. An infrared imaging microbolometer according to claim 1, wherein the microbolometer also comprises:
a lower resistive layer arranged between the support layer and the electrodes; and
an upper resistive layer arranged between the electrodes and the upper encapsulation layer of the holding arms;
the lower and upper resistive layers being in continuity with each other between ends of the electrodes extending within the membrane, thereby forming an insulating barrier between the electrodes, thus enabling to increase the surface area of the electrodes extending within the membrane.

7. An infrared imaging microbolometer according to claim 6, wherein the lower and upper resistive layers have an electric resistivity greater than 10⁴ Ohm·cm.

8. An infrared imaging microbolometer according to claim 6, wherein the lower and upper resistive layers are made of hafnium dioxide, of silicon nitride, of silicon oxide, of silicon oxynitride, of boron nitride, of aluminum nitride, of silicon carbide, of silicon carbonitride, of silicon boride, of silicon oxyboride, of silicon boronitride, of silicon borocarbide, or of silicon oxycarbide.

9. An infrared imaging microbolometer according to claim 1, wherein the thermoresistive material is made of an amorphous alloy having a high content of silicon, of vanadium oxide, of titanium oxide, or of nickel oxide.

10. An infrared imaging microbolometer according to claim 1, wherein the electrodes are made of metal, selected from the group comprising titanium, copper, chromium, cobalt, and aluminum.
